(19) United States
(12) Patent Application Publication
(10) Pub. No.: US 2020/0402967 A1
(43) Pub. Date: Dec. 24, 2020

(54) DISPLAY DEVICE

(71) Applicant: SHARP KABUSHIKI KAISHA, Osaka (JP)

(72) Inventor: YASUHIRO YOSHIDA, Osaka (JP)

(21) Appl. No.: 16/906,711

(22) Filed: Jun. 19, 2020

Related U.S. Application Data
(60) Provisional application No. 62/865,485, filed on Jun. 24, 2019.

(51) Int. Cl. H01L 25/18; H01L 23/00

(52) U.S. Cl. CPC H01L 25/18; H01L 2224/49111; H01L 24/48; H01L 24/73; H01L 24/49; H01L 2224/32145; H01L 2224/48106; H01L 2224/48108; H01L 2224/48227; H01L 2224/4824; H01L 2224/73215; H01L 2224/4903; H01L 2224/49175; H01L 2224/49177; H01L 24/32

(57) ABSTRACT

A display device includes: an array substrate including a display area, of an image, including a plurality of pixels arranged in an array; a first circuit that is disposed at the array substrate to face an end of the display area, and controls drive of the plurality of pixels; and a second circuit that controls drive of the first circuit. The first circuit includes a plurality of first terminals arranged on the array substrate. The first circuit includes a plurality of second terminals each connected by at least one wire bond to a corresponding one of a plurality of terminals included in the second circuit.

### TECHNICAL FIELD

An aspect of the present invention relates to a display device.

### BACKGROUND

Japanese Unexamined Patent Publication Application No. 2006-243322 discloses a display module in which a display panel and a control substrate are electrically connected to each other by a flexible board. FIG. 14 is a cross-sectional view illustrating a configuration of a display device 101 according to a related art. The display device 101 includes: a display panel 102; a backlight 103; a driver IC 120; and flexible printed circuits (FPC or flexible substrates) 150. The display panel 102 is a liquid crystal display panel, and includes: an array substrate 105; a counter substrate 106; and optical films 107 and 108 acting as polarizer plates. Here, the array substrate 105 and the counter substrate 106 are arranged to face each other through a liquid crystal layer.

The array substrate 105 includes a first face 105a on which TFT elements, each disposed for a pixel, are arranged in an array. Moreover, the array substrate 105 has an end 105c. Provided near the end 105c is a mounting area 105a1 for mounting: the driver IC 120; and an end 150a of the FPC 150. In the mounting area 105a1, the array substrate 105 is exposed without facing the counter substrate 106. Arranged on the mounting area 105a1 are: a plurality of terminals 105d1 and a plurality of terminals 105d2 for mounting the driver IC 120; and a plurality of terminals 105e for mounting the end 150a of the FPC 150.

The driver IC 120 and the end 150a of the FPC 150 are mounted on the mounting area 105a1 by the so-called chip-on-glass (COG) technique. The driver IC 120 is a source driver, and disposed in the mounting area 105a1 placed (i) outside an end of a display area for an image, and (ii) in the array substrate 105. The driver IC 120 includes a plurality of terminals 121 acting as output terminals and making contact with, and secured to, the terminals 105d1. The driver IC 120 also includes a plurality of terminals 122 acting as input terminals and making contact with, and secured to, the terminals 105d2. The end 150a of the FPC 150 is provided with a plurality of terminals making contact with, and secured to, the terminals 105e. The driver IC 120 and the FPC 150 are secured to the mounting area 105a1, using a bonding member 140 containing conductive particles.

The FPC 150 protrudes from the end 150a, mounted on the mounting area 105a1, further outside the end 105c of the array substrate 105. Then, the FPC 150 are folded to extend along the back face of the backlight 103. The FPC 150 have another end 150b connected to a circuit 130.

The circuit 130 includes such a circuit component as a timing controller to control the drive of the driver IC 120. The circuit 130 outputs an electric signal, which travels through the FPC 150, the end 150a, the terminals 105e, the terminals 105d2, and the terminals 122. The electric signal is then input to the driver IC 120. Based on the input electric signal, the driver IC 120 generates a source signal for driving each of pixels. The driver IC 120 outputs the source signal from the terminals 121 and the terminals 105d1 through routing lines to each of source lines. This is how to control the drive of the pixels.

In the display device 101, the FPC 150 have a folded portion protruding from the end 150a outside the end 105c of the array substrate 105. Hence, as shown by an arrow A100, the FPC 150 receive a reaction force to be applied between the folded portion and the end 150a in order to restore the FPC 150 to the original state. Due to this reaction force, some of the terminals provided to the end 150a of the FPC 150 come off some of the terminals 105e in the mounting area 105a1. Thus, some of the end 150a of the FPC 150 could separate from some of the terminals 105e in the mounting area 105a1. Hence, if some of the terminal 150a of the FPC 150 separates from the mounting area 105a1, the separated portion does not conduct the electric signal. As a result, the separation is a cause of deterioration in quality of an image to be displayed on the display device 101. As aspect of the present invention intends to suppress a deterioration in quality of an image to be displayed on a display panel.

### SUMMARY

A display device according to a first aspect of the present invention includes: an array substrate including a display area, of an image, including a plurality of pixels arranged in an array; a first circuit that is disposed at the array substrate to face an end of the display area, and controls drive of the plurality of pixels; and a second circuit that controls drive of the first circuit. The first circuit includes a plurality of first terminals arranged on the array substrate. The first circuit includes a plurality of second terminals each connected by at least one wire bond to a corresponding one of a plurality of terminals included in the second circuit.

In the display device of a second aspect of the present invention according to the first aspect, the first circuit overlaps with the end of the array substrate, and protrudes outside the end of the array substrate.

In the display device of a third aspect of the present invention according to the first or second aspect, the second circuit is disposed on a second face of the array substrate on an opposite side from a first face, of the array substrate, on which the first circuit is disposed.

In the display device of a fourth aspect of the present invention according to any one of the first to third aspects, the plurality of first terminals included in the first circuit are secured to the array substrate by a boding member.

In the display device of a fifth aspect of the present invention according to any one of the first to fourth aspects, the at least one wire bond includes a plurality of wire bonds, and at least one of the plurality of second terminals included in the first circuit is connected to at least one of the plurality of terminals in the second circuit by the plurality of wire bonds.

In the display device of a sixth aspect of the present invention according to any one of the first to fifth aspects, the at least one wire bond includes a plurality of wire bonds, and at least one of the plurality of wire bonds is different in line width.

### BRIEF DESCRIPTION OF DRAWINGS

FIG. 1 is a cross-section illustrating an example of a configuration of a display device according to an embodiment;

FIG. 2 is a plan view of a surface showing an example of a configuration of the display device according to the embodiment;

FIG. 3 is a plan view of a back face showing an example of a configuration of the display device according to the embodiment;

FIG. 4 is an enlarged plan view of an area B1 in FIG. 3, illustrating an example of a plurality of terminals of a driver IC, a plurality of terminals of a circuit, and a plurality of wire bonds;

FIG. 5 is a plan view illustrating another example of a configuration showing the terminals of the driver IC, the terminals of the circuit, and the wire bonds illustrated in FIG. 4.

FIG. 6 is a cross-section illustrating a configuration of a display device according to a first modification of the embodiment;

FIG. 7 is a plan view illustrating a terminal of the driver IC, a terminal of the circuit, and wire bonds included in the display device in FIG. 6;

FIG. 8 is a cross-section illustrating another example of the configuration of the display device according to the first modification of the embodiment, the cross-section showing the vicinity of a terminal of the driver IC and a terminal of the circuit;

FIG. 9 is a plan view illustrating the terminal of the driver IC, the terminal of the circuit, and the wire bonds included in the display device in FIG. 8;

FIG. 10 is a plan view partially illustrating wire bonds of the display device according to the first modification of the embodiment;

FIG. 11 is a cross-section illustrating a configuration of a display device according to a second modification of the embodiment;

FIG. 12 is a plan view illustrating the terminals of the driver IC, the terminals of the circuit, and a plurality of wire bonds included in the display device in FIG. 11;

FIG. 13 is a plan view partially illustrating the wire bonds of the display device according to the second modification of the embodiment; and

FIG. 14 is a cross-section illustrating a configuration of a display device according to a related art.

### DESCRIPTION OF EMBODIMENTS

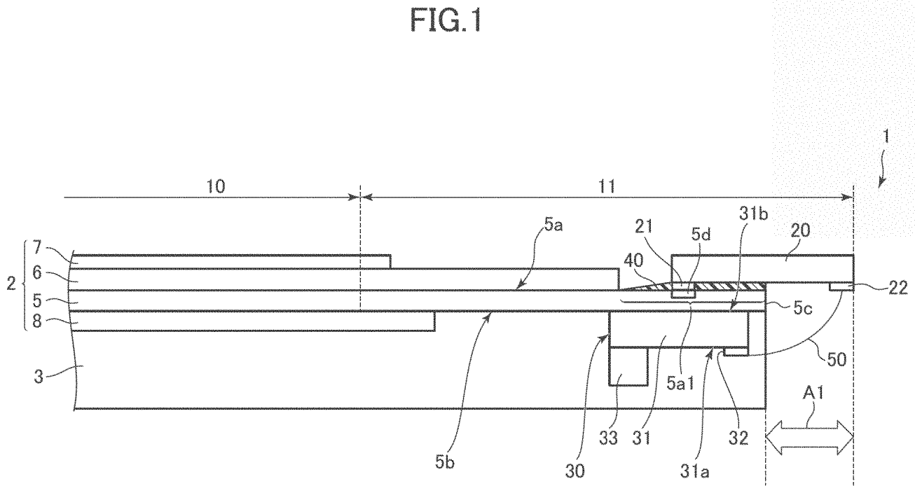

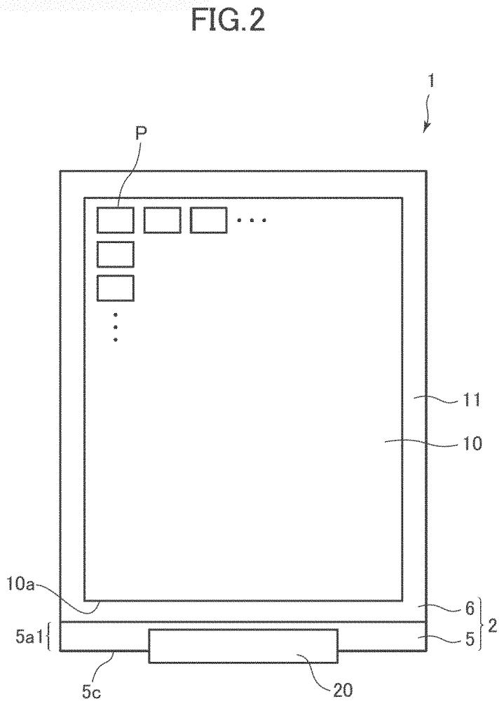

Described below is an embodiment of the present invention, with reference to the drawings. Note that, like reference signs designate identical or corresponding components throughout the drawings. Such components will not be described repeatedly. FIG. 1 is a cross-sectional view illustrating an example of a configuration of a display device 1 according to the embodiment. FIG. 2 is a plan view of a surface showing an example of a configuration of the display device 1 according to the embodiment. The surface of the display device 1 illustrated in FIG. 2 is one of two faces of the display device 1, which includes a face to display an image. Described below with reference to FIGS. 1 and 2 is an example of a configuration of the display device 1 according to a first embodiment. In this embodiment, the display device 1 is described as a liquid crystal display device. Alternatively, the display device 1 may be another display device, capable of displaying an image, such as an organic electro luminescence (EL) display device provided with an organic light-emitting diode (OLED).

As illustrated in FIG. 2, the display device 1 includes: a display area 10, of an image, including a plurality of pixels P arranged in an array; and a frame area 11 surrounding the display area 10 of the image. Moreover, as illustrated in FIGS. 1 and 2, the display device 1 includes: a display panel 2; a backlight 3; a driver IC (a first circuit) 20; and a circuit (a second circuit) 30. The display panel 2 includes: an array substrate 5; a counter substrate 6; and optical films 7 and 8.

The counter substrate 6 is disposed to face the array substrate 5 through a liquid crystal layer. The array substrate 5 includes: a first face 5a facing the counter substrate 6; and a second face 5b on an opposite side from the first face 5a. The optical films 7 and 8 are, for example, various kinds of optical films such as polarizer plates. The optical film 7 is disposed on a face, of the counter substrate 6, on an opposite side from a face, of the counter substrate 6, facing the array substrate 5. The optical film 8 is disposed on the second face 5b, of the array substrate 5, on an opposite side from the face, of the array substrate 5, facing the counter substrate 6. The backlight 3 is disposed to face the second face 5b of the array substrate 5 and the optical film 8. The backlight 3 illuminates the display panel 2 from the back face.

Arranged on the first face 5a of the array substrate 5 are a plurality of TFT elements each of which is disposed for each of the pixels P. Furthermore, arranged on the first face 5a of the array substrate 5 are: a plurality of source lines connected to source terminals of the TFT elements; and a plurality of gate lines connected to gate terminals of the TFT elements. The plurality of source lines and the plurality of gate lines are arranged to intersect with one another within the display area 10. The plurality of source lines and the plurality of gate lines are connected to a plurality of routing lines provided from an inside of the display area 10 to an inside of the external frame area 11. The plurality of routing lines run close to an end 5c of the array substrate 5.

Near the end 5c of the array substrate 5, a mounting area 5a1 is provided for mounting the driver IC 20. The mounting area 5a1 is provided along the end 5c of the array substrate 5 and an end 10a of the display area 10. In the mounting area 5a1, the array substrate 5 is exposed without facing the counter substrate 6. The array substrate 5 includes a plurality of terminals 5d arranged for mounting the driver IC 20. The plurality of terminals 5d are arranged along the end 5c, and connected to the routing lines connected to either the gate lines or the source lines.

Based on an electric signal from the circuit 30, the driver IC 20 controls the drive of the TFT elements disposed in the pixels P. The driver IC 20 may be, for example, a gate driver or a source driver driving the pixels. The driver IC 20 faces the end 10a of the display area 10, and is disposed in the mounting area 5a1 of the array substrate 5.

The circuit 30 controls the drive of the driver IC 20. The circuit 30 includes: a circuit substrate 31; a plurality of terminals 32; and a driver IC 33. The circuit substrate 31 is, for example, a printed wiring board (PWB). The circuit substrate 31 includes a first face 31a on which the plurality of terminals 32 and the driver IC 33 are arranged. The plurality of terminals 32 and the driver IC 33 are electrically connected to each other. The circuit substrate 31 includes a second face 31b disposed on an opposite side from the first face 31a and on the second face 5b of the array substrate 5. The plurality of terminals 32 are output terminals through which the driver IC 33 output an electric signal. The driver IC 33 may be, for example, a timing controller, a power source for generating a voltage to be supplied to the pixels P, or another circuit component for controlling the drive of the driver IC 20.

As can be seen in this embodiment, the driver IC 20, which is a circuit component for controlling the drive of the pixels P, is disposed on the first face 5a of the array substrate 5. The circuit 30 for controlling the drive of the driver IC 20 is disposed on the second face 5b of the array substrate 5 on an opposite side from the first face 5a of the array substrate 5.

The driver IC 20 includes: a plurality of terminals 21 acting as output terminals; and a plurality of terminals 22 acting as input terminals. The plurality of terminals 21 make contact with the plurality of terminals 5d in the mounting area 5a1 on the first face 5a of the array substrate 5. The plurality of terminals 21 are secured by a bonding member 40 containing conductive particles. That is, the plurality of terminals 21 included in the driver IC 20 are mounted on the mounting area 5a1 by the so-called chip-on-glass (COG) technique.

Meanwhile, an area, of the driver IC 20, near the arranged terminals 22 protrudes outside the end 5c of the array substrate 5 as indicated by an arrow A1. The plurality of terminals 22 do not overlap with the array substrate 5. Each of the plurality of terminals 22 is connected by at least one wire bond 50 to a corresponding one of the plurality of terminals 32 of the circuit 30.

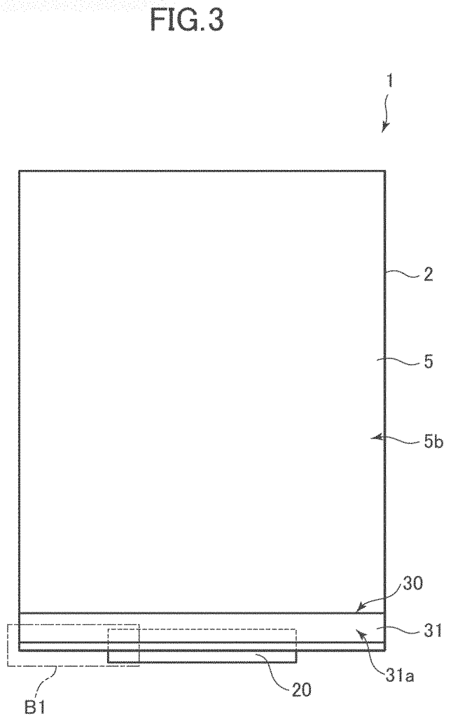

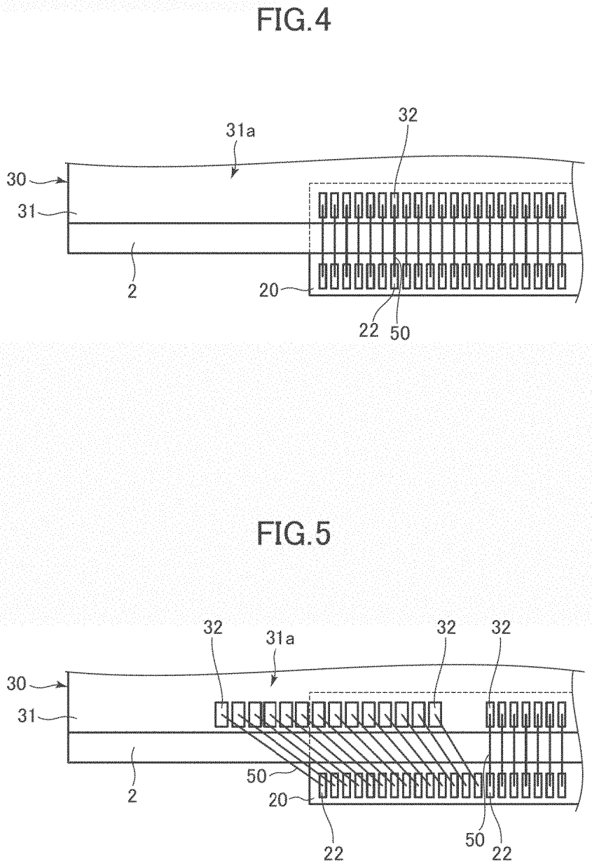

FIG. 3 is a plan view of a back face showing an example of a configuration of the display device 1 according to the embodiment. The back face of the display device 1 illustrated in FIG. 3 is one of two faces of the display device 1, which is on an opposite side from the other face (illustrated in FIG. 2) on which an image is displayed. FIG. 4 is an enlarged plan view of an area B1 in FIG. 3, illustrating an example of a plurality of terminals of a driver IC, a plurality of terminals of a circuit, and a plurality of wire bonds.

As illustrated in FIG. 4, for example, in this embodiment, one terminal 22 is connected to corresponding one terminal 32 with corresponding one wire bond 50. In the example illustrated in FIG. 4, the terminal 22, the terminal 32, and the wire bond 50 connecting the terminal 22 and the terminal 32 together are aligned in a straight line. FIG. 5 is a plan view illustrating another example of a configuration showing a plurality of terminals of the driver IC, a plurality of terminals of the circuit, and a plurality of wire bonds illustrated in FIG. 4. As illustrated in FIG. 5, the terminal 22, the terminal 32, and the wire bond 50 connecting the terminal 22 and the terminal 32 together may be aligned at an angle.

As illustrated in FIGS. 1, 4, and 5, the plurality of terminals 22 and the plurality of terminals 32 are connected together with the plurality of wire bonds 50, so that the electric signal generated by the driver IC 33 is input to the driver IC 20 through the plurality of terminals 32, the plurality of wire bonds 50, and the plurality of the terminals 22. Then, based on the input electric signal, the driver IC 20 generates a drive signal (e.g., a source signal or a gate signal) for driving each of the pixels. Then, from the plurality of terminals 21 and the plurality of terminals 5d, the driver IC 20 outputs through routing lines the drive signal to each of the source lines or each of the gate lines. This is how the driver IC 20 controls the drive of each of the pixels P.

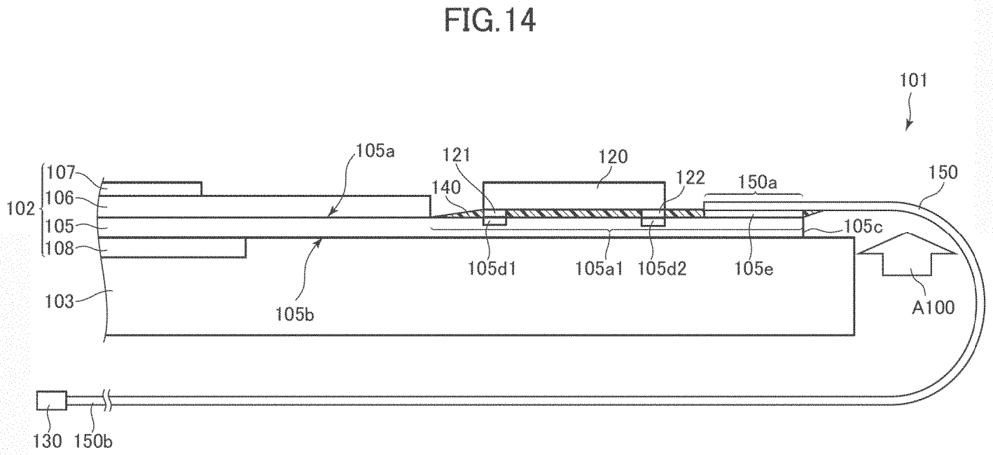

As to the display device 1, in the driver IC 20 controlling the drive of the pixels P, the plurality of terminals 21 are arranged on the array substrate 5, and the plurality of terminals 22 are connected by the plurality of wire bonds 50 to the plurality of terminals 32 of the circuit 30 controlling the drive of the driver IC 20. Hence, the display device 1 is different from the display device 101 described with reference to FIG. 14, eliminating the need of the FPC 150 for outputting an electric signal to the driver IC 120 disposed on the array substrate 105. Then, the wires of the wire bonds 50 used for the display device 1 are thinner than the FPC 150. Hence, even if the wires are folded, a reaction force due to the folded wires is smaller than that due to the folded FPC 150. Such a feature makes it possible to prevent some of the plurality of terminals 22 from coming off some of the plurality of wire bonds 50 because of the reaction force of the wires. Hence, the display device 1 makes it possible to prevent some of the plurality of terminals 22 of the driver IC 20 and some of the plurality of terminals 32 of the circuit 30 from being non-conductive. As a result, the display device 1 can prevent deterioration in quality of an image to be displayed on the display device 1.

Furthermore, in the display device 101 described with reference to FIG. 14, arranged and mounted on the mounting area 105a1 are: the plurality of terminals 105d1 acting as output terminals of the driver IC 120; the plurality of terminals 105d2 acting as input terminals of the driver IC 120; and the end 150a of the FPC 150. Hence, the mounting area 105a1 needs to have a width (a length between the plurality of terminals 105e and an end of the area facing the counter substrate 106) greater than a width in which the driver IC 120 and the end 150a of the FPC 150 are combined together.

Moreover, in the display device 101, the FPC 150 protrudes from the end 150a outside the end 105c. Then, the FPC 150 are folded to extend along the back face of the backlight 103. This configuration requires a width ranging from the end 105c to a tip end of a portion, of the FPC 150, protruding outside the end 105c and folded. This configuration of the display device 101 makes it difficult to narrow the width of the frame area outside the display area (i.e., to narrow the frame area).

Meanwhile, in the display device 1, the plurality of terminals 22 acting as the input terminals of the driver IC 20 are connected to the plurality of terminals 32 of the circuit 30 by the plurality of wire bonds 50. Hence, in the driver IC 20, the plurality of terminals 21 acting as the output terminals may be arranged in the mounting area 5a1 of the array substrate 5; whereas, the plurality of terminals 22 acting as the input terminals do not have to be arranged in the mounting area 5a1.

Such a feature makes it possible to dispose the driver IC 20 on the array substrate 5 so as to overlap with the end 5c of the array substrate 5. That is, as indicated by the arrow A1 of FIG. 1, the area near the plurality of terminals 22 can protrude outside the end 5c of the array substrate 5. Such a feature makes it possible to reduce the width of the mounting area 5a1 narrower than the width between the plurality of terminals 21 and plurality of the terminals 22 of the driver IC 20. Compared with the configuration, of the display device 101 described with reference to FIG. 14, in which the mounting area 105a1 is provided with both of the plurality of terminals 121 and the plurality of terminals 122 of the driver IC 120, the feature makes it possible to narrow the width of the mounting area 5a1. Hence, the feature makes it possible to narrow the width of the frame area 11 of the display device 1; that is, the frame area 11 can be reduced in width.

Moreover, the display device 1 does not include FPC, and, unlike the display device 101 described with reference to FIG. 14, eliminates the need for securing an area, of the mounting area 105a1, in which the end 150a of the FPC 150 is to be disposed. Hence, the frame area 11 of the display device 1 can be reduced in width.

In addition, the display device 1 does not use the FPC. Thus, unlike the display device 101 described with reference to FIG. 14, the display device 1 eliminates the need of a portion, of the FPC 150, protruding outside the end 105c of the array substrate 105 and folded. Hence, the frame area 11 of the display device 1 can be reduced in width.

Furthermore, in the display device 1, the plurality of terminals 22 of the driver IC 20 are connected to the plurality of terminals 32 of the circuit 30 by the wire bonds 50. Such a feature allows the circuit 30 to be disposed on the second face 5b of the array substrate 5 on an opposite side from the first face 5a, of the array substrate 5, on which the driver IC 20 is disposed. Compared with the case where the driver IC 20 and the circuit 30 are disposed on the same face of the array substrate 5, the feature makes it possible to narrow the frame area 11.

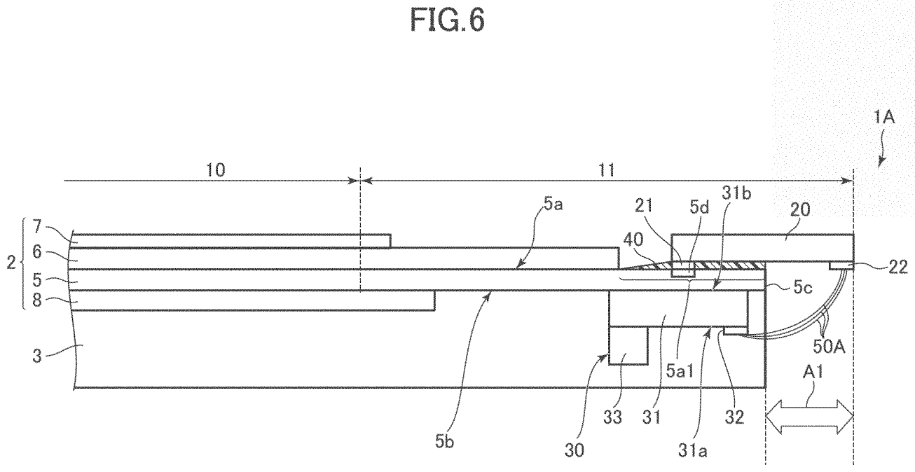

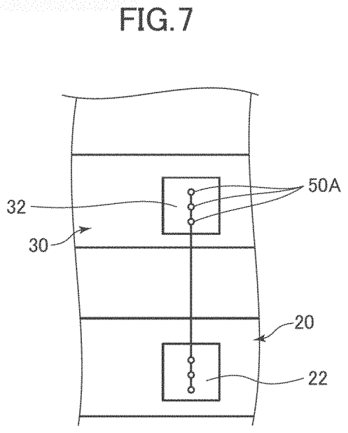

FIG. 6 is a cross-sectional view illustrating a configuration of a display device 1A according to a first modification of the embodiment. FIG. 7 is a plan view illustrating a terminal 22 of the driver IC 20, a terminal 32 of the circuit 30, and a plurality of wire bonds 50A included in the display device 1A in FIG. 6. As seen in the display device 1A illustrated in FIGS. 6 and 7, one terminal 22 and one terminal 32 are connected together by the plurality of wire bonds 50A. Even if the driver IC 33 is, for example, a power source, such a feature makes it possible to supply great power from the circuit 30 to the driver IC 20. In the examples illustrated in FIGS. 6 and 7, one terminal 22 and one terminal 32 are connected together by three wire bonds 50A. Furthermore, in the examples illustrated in FIGS. 6 and 7, the plurality of wire bonds 50A connecting the one terminal 22 and the one terminal 32 together are arranged to overlap with one another in plan view.

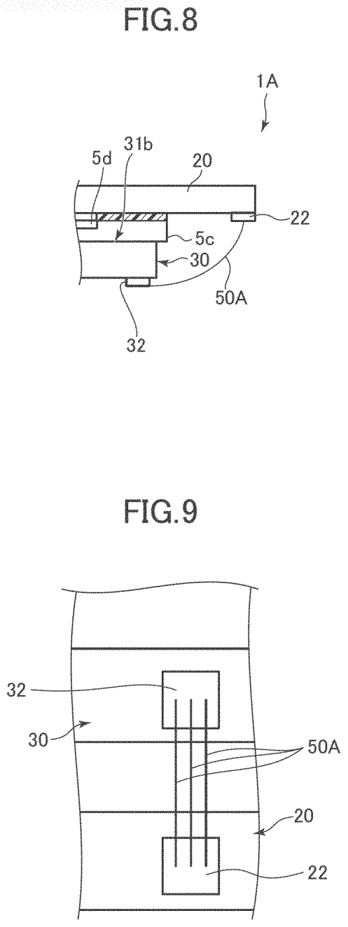

FIG. 8 is a cross-sectional view illustrating another example of the configuration of the display device 1A according to the first modification of the embodiment, the cross-sectional view showing the vicinity of a terminal 22 of the driver IC 20 and a terminal 32 of the circuit 30. FIG. 9 is a plan view illustrating the terminal 22 of the driver IC 20, the terminal 32 of the circuit 30, and the plurality of wire bonds 50A included in the display device 1A in FIG. 8. As seen in the display device 1A illustrated in FIGS. 8 and 9, the plurality of wire bonds 50A connecting one terminal 22 and one terminal 32 together may be arranged, for example, side-by-side not to overlap with one another in plan view.

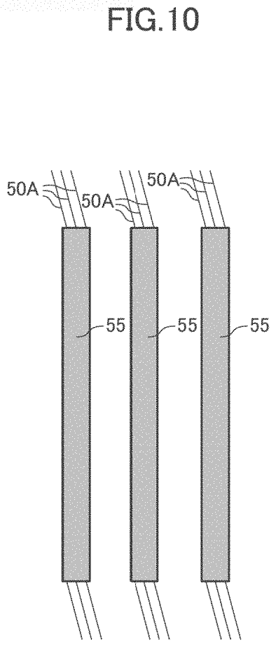

FIG. 10 is a plan view illustrating some of the wire bonds 50A of the display device 1A according to the first modification of the embodiment. As illustrated in FIG. 10, the plurality of wire bonds 50A connecting one terminal 22 and one terminal 32 together may be bound by a binding member 55, so that the plurality of wire bonds 50A bound by each binding member 55 may connect the one terminal 22 and the one terminal 32 together.

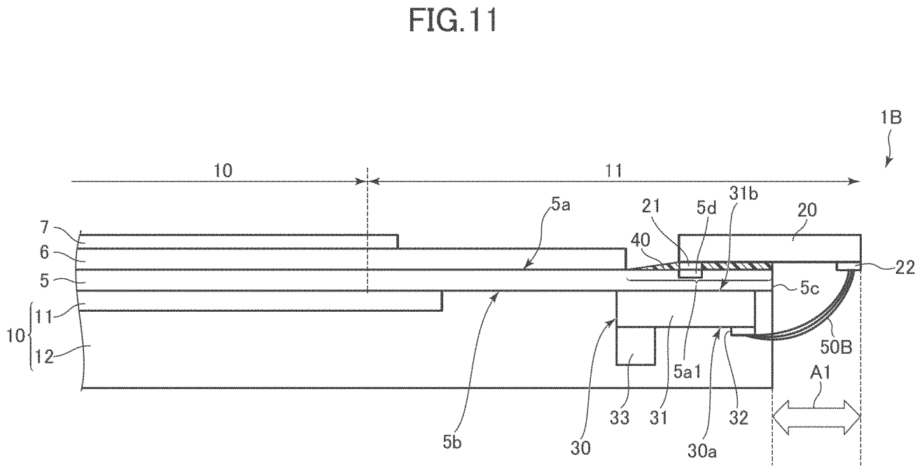

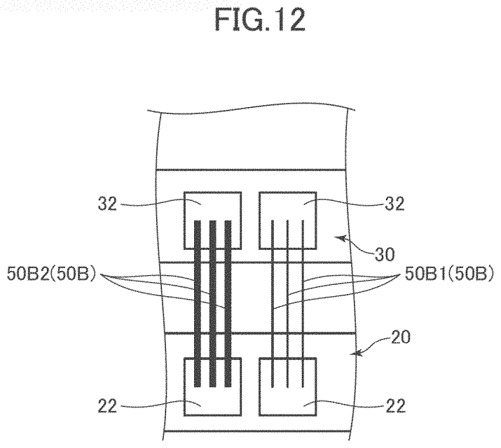

FIG. 11 is a cross-sectional view illustrating a configuration of a display device 1B according to a second modification of the embodiment. FIG. 12 is a plan view illustrating the terminals 22 of the driver IC 20, the terminals 32 of the circuit 30, and a plurality of wire bonds 50B included in the display device 1B in FIG. 11.

As seen in the display device 1B illustrated in FIGS. 11 and 12, at least one of the plurality of wire bonds 50B may be larger in line width than the other wire bonds 50B. As illustrated in FIG. 12, for example, the plurality of wire bonds 50B may be different in line width for each pair of the terminal 22 and the terminal 32. In the example illustrated in FIG. 12, a plurality of wire bonds 50B2 connecting a pair of the terminal 22 and the terminal 32 are larger in line width than a plurality of neighboring wire bonds 50B1 connecting another pair of the terminal 22 and the terminal 32. Even if the driver IC 33 is, for example, a power source, such a feature also makes it possible to supply great power from the circuit 30 to the driver IC 20.

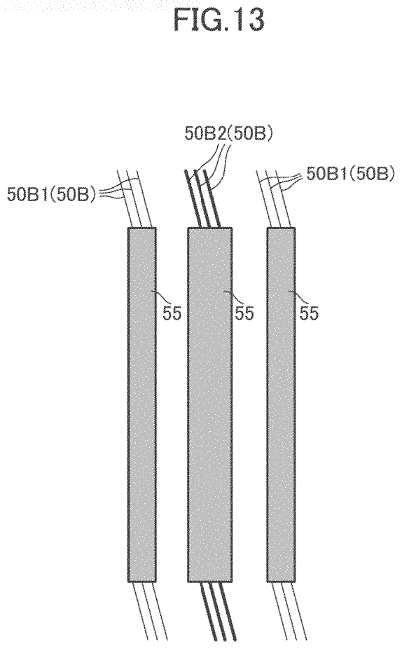

FIG. 13 is a plan view illustrating some of the wire bonds 50B of the display device 1B according to the second modification of the embodiment. As illustrated in FIG. 13, the plurality of wire bonds 50B connecting one terminal 22 and one terminal 32 together may be bound by the binding member 55, so that the plurality of wire bonds 50B bound by each binding member 55 may connect the one terminal 22 and the one terminal 32 together.

As aspect of the present invention makes it possible to suppress a deterioration in quality of an image to be displayed on a display panel.

The present invention shall not be limited to the above embodiment. The above embodiment may be replaced with substantially the same configuration, substantially the same configuration in advantageous effect, or substantially the same configuration in intended object.

What is claimed is:

1. A display device comprising:
an array substrate on which a plurality of pixels are arranged in an array;
a first circuit that is disposed at an end of the array substrate, and controls drive of the plurality of pixels; and
a second circuit that controls drive of the first circuit, wherein
the first circuit includes a plurality of first terminals arranged on the array substrate, and
the first circuit includes a plurality of second terminals each connected by at least one wire bond to a corresponding one of a plurality of terminals included in the second circuit.

2. The display device according to claim 1, wherein
the first circuit overlaps with the end of the array substrate, and protrudes outside the end of the array substrate.

3. The display device according to claim 1, wherein
the second circuit is disposed on a second face of the array substrate on an opposite side from a first face, of the array substrate, on which the first circuit is disposed.

4. The display device according to claim 1, wherein
the plurality of first terminals included in the first circuit are secured to the array substrate by a boding member.

5. The display device according to claim 1, wherein
the at least one wire bond includes a plurality of wire bonds, and
at least one of the plurality of second terminals included in the first circuit is connected to at least one of the plurality of terminals in the second circuit by the plurality of wire bonds.

6. The display device according to claim 1, wherein
the at least one wire bond includes a plurality of wire bonds, and
at least one of the plurality of wire bonds is different in line width.
